(19) United States
(12) Patent Application Publication
(10) Pub. No.: US 2026/0278776 A1
(43) Pub. Date: Sep. 17, 2026

(54) IMPROVED DETECTION OF SURFACE FEATURES ON MANUFACTURED PARTS ON A PRODUCTION LINE

(71) Applicant: Siemens Aktiengesellschaft, Munich (DE)

(72) Inventors: Baris Erol, Princeton, NJ (US); Pravar Kulbhushan, Mumbai (IN); Jacob Vishal, Mumbai (IN); Timo Döring, Munich (DE)

(73) Assignee: Siemens Aktiengesellschaft, Munich (DE)

(21) Appl. No.: 19/471,482

(22) PCT Filed: Apr. 26, 2023
(86) PCT No.: PCT/US2023/019969

§ 371 Date: Oct. 2, 2025

(51) Int. Cl. G06T 7/00; G06F 30/17; G06T 7/11; G06T 11/10; G06T 11/60

(52) U.S. Cl. CPC G06T 7/001; G06F 30/17; G06T 7/11; G06T 11/10; G06T 11/60; G06T 2207/20081; G06T 2207/20221; G06T 2207/30164; G06T 2210/12

(57) ABSTRACT

A system for vision-based inspection of manufactured parts on a production line includes an image renderer that generates multiple synthetic camera images of a part utilizing a CAD model of the part by simulating the inspection environment and the one or more cameras based on randomization of a number of operational and environmental parameters. An image labeler generates annotations i the synthetic camera images by automatically detecting nominal surface features on the part in the synthetic camera images. An image blender randomly superimposes background textures and/or artifacts on a part surface, which are obtained from a set of real images, on the synthetic camera images. Subsequently, a model trainer uses synthetic camera images with the generated annotations to train a machine learning model for detecting nominal surface features on real images of manufactured parts on the production line.

### TECHNICAL FIELD

The present disclosure relates to computer vision systems for inspection of manufactured parts on a production line. Embodiments of the disclosure specifically relate to systems, methods and computer program products for vision-based inspection to detect surface features on manufactured parts using machine learning.

### BACKGROUND

Surface inspection is an important use-case in production across many different industries. For example, in automotive manufacturing, there may be thousands of small and larger parts in an automotive body-in-white and fully assembled car. Most of these parts contain surface features, such as holes and logos, to be utilized during assembly or any other downstream manufacturing processes. For example, holes may be utilized for fastening different parts via spot welding, screwing, etc. Logos may be used, for example, to distinguish between parts belonging to different trims.

Parts may be manufactured independently via different processes, such as stamping, die-casting, injection molding, among others. Any production faults, such as a missing a hole, can cause a significant safety risk to end customers if undetected. Additionally, undetected defects can add into the possible scrap cost to the original equipment manufacturer (OEM) if detected later in the production.

Currently, OEMs mostly rely on a sampling-based manual process of counting and measurement of holes. An alternative approach is to use traditional computer vision, where a user can define sequential filters on the camera images for detection. This approach, however, is not generalizable across different parts and is furthermore prone to high false positives due to its sensitivity to environmental and operational changes. Improved systems are desirable.

### SUMMARY

Briefly, aspects of the present disclosure provide an automated and generalizable solution for detecting surface features on manufactured parts on a production line using machine learning, that can address the above-mentioned technical challenges.

A first aspect of the disclosure provides a system for vision-based inspection of manufactured parts on a production line using one or more cameras in an inspection environment. The system comprises one or more processors, and a non-transitory memory storing algorithmic modules executable by the one or more processors. The algorithmic modules comprise an image renderer configured to generate multiple synthetic camera images of a part utilizing a CAD model of the part by simulating the inspection environment and the one or more cameras based on randomization of a number of operational and environmental parameters. The algorithmic modules further comprise an image labeler configured to generate annotations in the synthetic camera images by automatically detecting nominal surface features on the part in the synthetic camera images. The algorithmic modules further comprise an image blender configured to process the synthetic camera images by randomly superimposing background textures and/or artifacts on a part surface, which are obtained from a set of real images, on the synthetic camera images. The algorithmic modules further comprise a model trainer configured to utilize the processed synthetic camera images and the generated annotations to train a machine learning model to detect the nominal surface features on real images of manufactured parts on the production line captured by the one or more cameras in the inspection environment.

Other aspects of the disclosure implement features of the above-described system in computer-implemented methods and computer program products for vision-based inspection of manufactured parts on a production line.

Additional technical features and benefits may be realized through the techniques of the present disclosure. Embodiments and aspects of the disclosure are described in detail herein and are considered a part of the claimed subject matter. For a better understanding, refer to the detailed description and to the drawings.

### BRIEF DESCRIPTION OF THE DRAWINGS

The foregoing and other aspects of the present disclosure are best understood from the following detailed description when read in connection with the accompanying drawings. To easily identify the discussion of any element or act, the most significant digit or digits in a reference number refer to the figure number in which the element or act is first introduced. For clarity, some of the images herein are schematically represented as line drawings.

FIG. 1 is a schematic diagram illustrating a pipeline for training a machine learning model for detection of nominal surface features on manufactured parts on a production line according to an embodiment.

FIG. 2 illustrates an example of a synthetic camera image of a part generated by an image renderer.

FIG. 3 illustrates an example of addition of real background texture on a synthetic camera image.

FIG. 4 illustrates an example of addition of artifacts on part surfaces on a synthetic camera image.

FIG. 5 schematically illustrates different modalities of patch extraction according to disclosed embodiments.

FIG. 6 is a schematic diagram illustrating a vision-based inspection system for a production line according to an embodiment.

FIG. 7 is a block diagram illustrating a workflow for fusion of inference results for defect detection according to an embodiment.

FIG. 8 illustrates a computing system that can support vision-based inspection of parts on a production line according to disclosed embodiments.

### DETAILED DESCRIPTION

Machine learning models, such as deep neural networks, can be used to detect and localize objects in images. Such models may need to be trained on large datasets, which may comprise real images with appropriate object labels which serve as ground truths for training the models. From experimentation with industrial inspection use-cases, the present inventors recognize that machine learning models can be very sensitive to environmental and operational changes, such as lighting changes, changes in position (e.g., rotation) of the manufactured parts, adaptation to unseen parts, etc. Furthermore, creating a labeled dataset for an industrial inspection use-case typically requires significant manpower and labeling effort. The disclosed methodology can provide an automated and generalizable solution for vision-based inspection of manufactured parts on a production line.

According to the disclosed methodology, a machine learning model is trained to detect nominal surface features on real images of manufactured parts being inspected, using a training dataset comprising synthetic camera images. A “nominal surface feature” refers to a surface feature on a part that is provided by design (e.g., a hole or a logo), which may, for example, be utilized in a downstream manufacturing process. The synthetic camera images are generated utilizing CAD models of the parts by performing camera simulation and environment simulation based on randomization environmental and operation parameters, thereby accounting for a large amount of variability in the manufacturing process. Using a CAD model can help account for each nominal surface feature of interest and its position on the part. By simulating cameras, it can be ensured that the synthetic images used for model training are similar (e.g., having similar fields of views) to real images captured by cameras in the actual inspection environment. By randomization of environmental and operational parameters, it can be ensured that the machine learning model is generalizable to different real-world scenarios on the production line, such as different backgrounds, variation in ambient lighting, part rotation, part speed etc.

Because of the above-described process variability, the machine learning model may have to be trained on a large dataset to be more robust. The disclosed methodology can obviate manual labeling effort by using an image labeler that can automatically generate labels or annotations in the synthetic camera images based on a 2D and/or 3D detection of nominal surface features on the part in the synthetic camera images. This can enable a user to obtain the synthetic camera images and corresponding annotations (e.g., bounding boxes) around the nominal surface features in a single step, such as a mouse click.

The disclosed methodology further uses an image blender that can process the synthetic camera images by randomly superimposing background textures and/or artifacts on a part surface, which are obtained from real images, on the synthetic camera images. The processed synthetic camera images output by the image blender and the annotations output by the image labeler are utilized by a model trainer to train the machine learning model. The image blender, as disclosed herein, can minimize false positives and further generalize the machine learning model to a range of real-world scenarios.

In some embodiments, to account for high-resolution cameras used in modern industrial inspection environments, the disclosed methodology provides a patch extractor that can ensure that an image does not have to be resized to be usable by the machine learning model to a degree where the surface feature information is lost. Disclosed modalities of patch extraction can ensure that the machine learning model becomes more and more robust and generalizable to different parts and inspection environments while achieving faster cycle times.

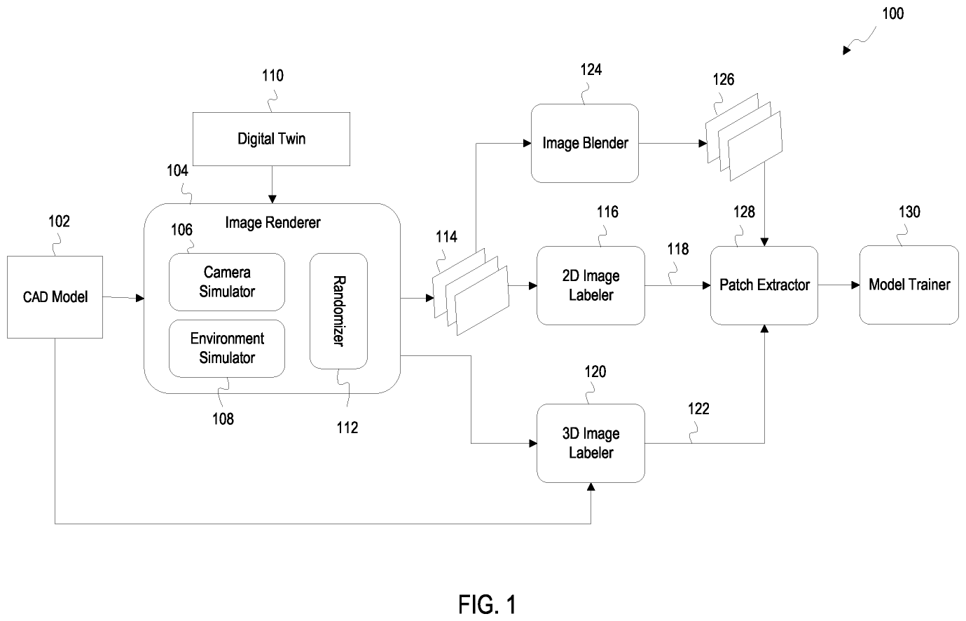

Turning now to the disclosed embodiments, FIG. 1 illustrates an example pipeline 100 for training a machine learning model for detection of nominal surface features on manufactured parts on a production line. The various modules, such as the image renderer 104, the image labeler(s) 116, 120, the image blender 124, patch extractor 128 and the model trainer 130, described herein, including components thereof, may be implemented by a computing system in various ways, for example, as hardware and programming. The programming for the modules 104, 116, 120, 124, 128,130 may take the form of processor-executable instructions stored on non-transitory machine-readable storage mediums and the hardware for the engines may include processors to execute those instructions. In embodiments, the computing system may suitably comprise a workstation having multiple graphics processing units (GPU).

In an example manufacturing use-case, parts may be manufactured by different upstream manufacturing processes, such as stamping, die-casting, injection molding, etc. and transferred to an inspection environment by a gantry, a robotized system, or any other type of transfer mechanism. The inspection environment may include an inspection station, for example, including a conveyor, on which a part to be inspected is placed. One or more cameras are arranged in the inspection environment, which may be triggered to capture respective images of the part when the part is moved into a pre-defined position by the conveyor. In other embodiments, the inspection station may be stationary where there is no motion of the part during inspection and the inspection environment may comprise one or more robots capable of manipulating the position of the one or more cameras.

Referring to FIG. 1, the image renderer 104 may comprise a 3D simulation engine that can generate synthetic camera images 114 of manufactured parts, utilizing, in each case, a CAD model 102 of the respective part (e.g., described in a STEP file format). A non-limiting example of a commercially available 3D simulation engine suitable for the present application is Process Simulate™ developed by Siemens Industry Software Inc. In particular, as shown, the image renderer 104 may include a camera simulator 106 that can simulate the one or more cameras based on their position (e.g., location, angle, etc.) and camera parameters (e.g., exposure, color mode, resolution, analog gain, field of view, depth of focus, etc.) and an environment simulator 108 that can simulate the inspection environment (e.g., including the conveyor, ambient lighting, etc.).

In accordance with disclosed embodiments, a realistic simulation may be performed by the camera simulator 106 and environment simulator 108 using a digital twin 110 of an actual inspection system. The digital twin 110 may comprise a 3D model of the actual inspection system, for example, including the conveyor and other components of the transfer mechanism. The digital twin 110 may be created based on an overall system design, for example, using information pertaining to the cameras, line configuration and process parameters, among others. The camera information may include information such as location and design of the fixture to mount the cameras (e.g., array or grid, distance from inspection station, etc.), available number of cameras, candidate camera trigger locations, camera parameters (such as mentioned above), among others. The line configuration information may include, for example, inspection station background, conveyor speeds, ambient lighting conditions, line/station dimensions, part orientation, etc. The process parameters may include parameters related to the production process, such as shift or time of day, number of operators, etc.

The image renderer 104 may be configured to generate, for each part, multiple synthetic camera images 114 utilizing the CAD model 102 of the part by simulating the inspection environment and the one or more cameras based on randomization of a number of operational and environmental parameters. To that end, the image renderer 104 may include a domain randomizer 112 that can use a setup defined by the digital twin 110 as a basis to generate randomized operational and environmental parameters. Operational parameters randomized by the randomizer 112 may include, for example, at least some or all of: part orientation, part translation, conveyor speed, vibration in camera position (e.g., due to robot motion) and cycle time. Environmental parameters randomized by the randomizer 112 may include, for example, at least some or all of: conveyor dimensions, background (conveyor) color and texture, part color and texture and ambient lighting. The randomized parameters may be fed to the camera simulator 106 and the environment simulator 108 to generate a large number of synthetic camera images 114 for the given part. Each rendered synthetic camera image 114 may be identified by its respective meta data, which may be defined by parameter values of the randomized parameters.

In some embodiments, the image renderer 104 may be configured to generate the synthetic camera images 114 as photorealistic images. A photorealistic image is an image rendering that is based on simulation of the behavior of light, for example, using techniques such as ray tracing. A photorealistic image may thus have realistic lighting reflections as can be expected on a real shop floor. The photorealistic images may typically comprise RGB images (having red, green and blue channels of pixel intensities).

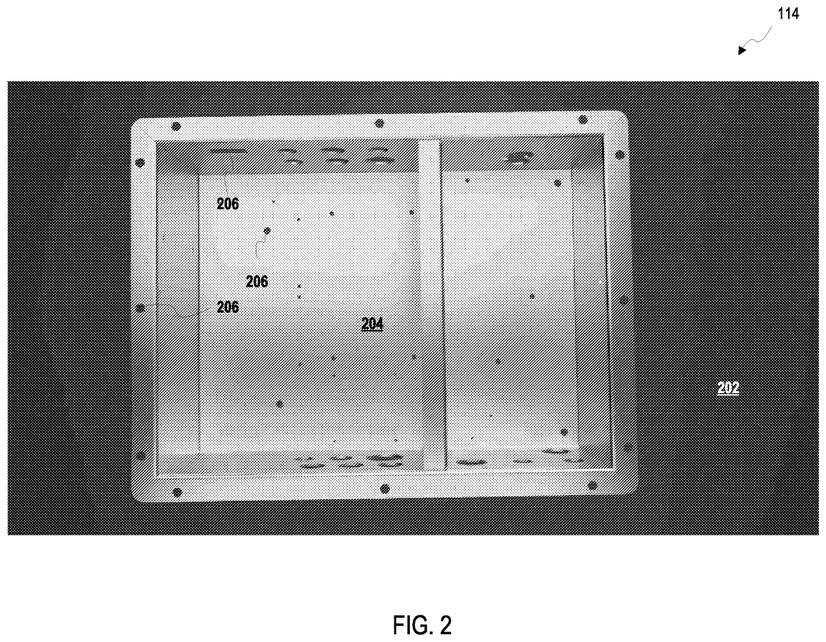

An example of a synthetic camera image 114 rendered by the image renderer 104 (converted to grayscale herein) is shown in FIG. 2. The image 114 shows a part 204 having the shape of an open box, which is captured with a top-down camera field of view. The background 202, in this example, is defined by a top surface of an inspection conveyor. The nominal surface features, in this example, include holes 206, which can be of various shapes and sizes.

Still referring to FIG. 1, the pipeline 100 may include one or more image labelers 116, 120 that can generate annotations in the synthetic camera images 114 by automatically detecting nominal surface features on the part in the synthetic camera images 114. In the present disclosure, two modalities image labelers are described, namely, a 2D image labeler 116 and a 3D image labeler 120. In embodiments, the pipeline 100 may include either one or both of these modalities of image labelers.

The 2D image labeler 116 may be particularly suitable for automatically detecting nominal holes on a part surface from a rendered synthetic camera image 114, such as shown in FIG. 2. In this case, the image renderer 104 may be configured to apply a uniform background color (in this example, conveyor color) respectively to each synthetic camera image 114. The background or conveyor color for each image 114 may be determined by the randomizer 112 in a randomized manner such that the background color is distinct from the part color in that image. This enables the 2D image labeler 116 to detect holes on each synthetic camera image 114 utilizing a segmentation mask determined based on the applied background color.

According to a disclosed embodiment, the 2D image labeler 116 may perform the following operations on each synthetic camera image 114. As an initial operation, the rendered synthetic camera image 114 may be processed to eliminate shadows from background objects (e.g., conveyor) on the part. The 2D image labeler 116 may convert the synthetic camera image 114, which may be in BGR (Blue Green Red) or RGB (Red Green Blue) color space, to HSV (Hue Saturation Value) color space. The segmentation mask may be readily defined by lower and upper limits in the HSV color space, based on the background color specified in the image meta data. The 2D image labeler 116 may segment the image 114 using the defined segmentation mask and determine contours in the segmented image bounding regions having the background color.

In order to detect nominal holes on the part surface (i.e., holes provided by design), the 2D image labeler 116 may identify regions bounded by contours whose area falls within a defined range. To carry out this operation, the regions bounded by contours may first be sorted by area from largest to smallest. The range may, for example, be defined by a maximum threshold and a minimum threshold. The maximum and minimum thresholds may be extracted from a configuration specification of the part, which may be described in a suitable file format, such as YAML. By applying a maximum threshold, larger openings on the part may be excluded from consideration. Applying a minimum threshold can exclude artifacts in the image, such as a small number of pixels on the part surface having background color, from being erroneously identified as holes. Finally, the 2D image labeler 116 may generate annotations 118 in the synthetic camera image 114 based on a position of each identified region. The annotations 118 may be generated, for example, by drawing bounding boxes around the identified holes. The generated annotations 118 may comprise a position of each bounding box in the image, which may be stored, for example, as coordinates (xmax, ymax) and (xmin, ymin) in a suitable format such as Pascal/COCO XML, among others.

An example pseudo code describing an implementation of the above-described operations performed by the 2D image labeler 116 is provided below. The operations may be implemented using a computer vision/machine learning software library, such as OpenCV, among others.

### Example: Automatic 2D Hole Labeling in Image

```
# Load the randomization meta data acquired from the simulation engine.
# This text file contains the information of each trial and corresponding
randomizations being applied.
meta_data = load_txt(“metadata_partID.txt”)
# Load in the config file for thresholds
configs = load_yaml(“config.yaml”)
# Loop around all images in local folder- note that this should match the
meta data
for each img in images:
  # Apply color space conversion BGR2HSV
  img_hsv = color_convert(img, BGR2HSV)
  # Define a mask using the background color
  mask = inRange(img_hsv, [low_lim, upp_lim])
  # Find the contours in the masked image and sort them from the
  largest to the smallest
  contours = sortContours(findContours(mask))
  # Loop around each contour
  for cont in contours :
    # Calculate the area of the contour
    cont_area = findArea(cont)
    # Check if contour area is in range defined by max and min
    thresholds provided in config file
    if min configs.area( )<=:cont_area <=max configs.area( ):
      # Draw the bounding box and put the position info to an
      xml
      drawBoundingbox( )
```

The 3D image labeler 120 does not rely on the rendered images 114 to generate annotations but may leverage information in the CAD model 102 of a part to extract positions of nominal surface features, such as holes/openings and logos on the part. The operations performed by the 3D image labeler 120 may be broadly divided into two steps. The first step may be performed based purely on the CAD model 102 without requiring any camera simulation at this point. The CAD model 102 may include a polygon mesh, such as a triangular mesh, that defines a number of planar surface elements, referred to as “faces”. In the first step, the 3D image labeler 120 may detect nominal surface features by checking if the faces in the CAD model 102 meet a set of conditions defined based on a geometrical property of the nominal surface features. The 3D image labeler 120 may generate 3D annotations in the CAD model 102 by extracting positions of the detected nominal surface features. The second step may be performed in conjunction with camera simulation. In the second step, the 3D image labeler 120 may transform the 3D annotations in the CAD model 102, which overlap with a simulated camera field of view, from a 3D CAD space to a 2D camera space, to generate annotations 122 in the rendered synthetic camera images 114.

According to a disclosed embodiment, the nominal surface features include holes, wherein 3D image labeler 120 may perform the following operations in the first step. First, the conditions for detecting a hole may be defined using a geometrical property of the hole. For example, for a cylindrical hole, the conditions may include: (i) the normal from the faces are directed inwards, (ii) the normal, after extending by radius, intersects with an axis of symmetry and (iii) the axis of symmetry is also extended by the height of the cylinder. The 3D image labeler 120 may apply the above conditions on each face in the CAD model 102 to determine if the faces in the CAD model 102 form one or more closed cylindrical surfaces. If the conditions are met, the 3D image labeler 120 may detect a hole and draw a 3D bounding box encapsulating the hole. The position of each bounding box in 3D space may be extracted to generate 3D annotations in the CAD model 102. The 3D annotations may be stored, for example, as coordinates (xmax, ymax, zmax) and (xmin, ymin, zmin) of each 3D bounding box.

An example pseudo code describing an implementation of the above-described operations performed in the first step by the 3D image labeler 120 is provided below.

### Example: Automatic 3D Hole Labeling in CAD Model

```
# Condition of a hole:
COND 1: A cylinder is a hole if the normal points are inwards
COND 2: Normal after extending by radius intersects
with axis of symmetry
COND 3: The axis of symmetry is also extended by height of cylinder
# Locating the holes and logos in CAD model
part_object = load_part(‘part1.step’)
# Check part is 3D solid
if part_object.properties.type == “3DSolid”:
  # Initialize the variables for entity and faces and 3d bbox
  list for each of them
  entityID, cylind_faces, 3d_bbox_list = [ ], [ ], [ ]
  # Loop around each face available in the part
  for each face in part_object.extract.faces( ):
    # Check if the face is cylindrical
    if face.properties.type == “cylinder”:
      # Check if the face is a cylindrical closed surface
      if face.closure == “closed”:
          # Access the surface normal from the face
          surface_normal = face.surfNormVector
          # Access the center point of the face
          center_point = face.surfCenterPoint
          # Check hole conditions
        hole_cond = check_ifhole(surface_normal, center_point)
          # If conditions are met store the face ID and
          current face
          If hole_cond == True:
            entityID.append(face.ID)
            cylind_faces.append(face)
            # Extract the 3D bounding box information
            encapsulation
            3d_bbox = extract_bbox_from_face(face)
            3d_bbox_list.append(3d_bbox)
```

In the second step, the following operations may be performed. First, for each camera position of the one or more cameras, a respective field of view (FOV) may be generated and extended by running the camera simulator 106. A FOV indicates what the camera is looking at and may be generated by the camera simulator 106 based on a global position (e.g., coordinates x. y. z) and angular orientation (e.g., rotation vectors Rx, Ry, Rz) of the camera. The generated FOV, when extended over the part, may define a rectangular 2D region overlapping with the part. For the FOV generated for each camera position, the 3D image labeler 120 may loop around the stored 3D annotations (which encapsulate faces forming cylindrical holes) on the CAD model 102 to check if a hole overlaps with the FOV. If yes, the position of the hole may be stored as meta data for the camera position. A transformation matrix may be applied to transform the 3D bounding box encapsulating the hole into a 2D bounding box using a geometrical relationship between the camera and the part used by the camera simulator 106 to generate the synthetic camera images 114.

The position of each 2D bounding box may be extracted to generate annotations 122 that can be attached to the synthetic camera images 114, generated based on operational and environmental randomization, which correspond to that camera position. The generated annotations 122 may comprise a position of each bounding box in the image, which may be stored, for example, as coordinates (xmax, ymax) and (xmin, ymin) in a suitable format such as Pascal/COCO XML, among others. Whenever the part is moved, for example, by randomizing part position or orientation, the same transformation may be applied in each case to the 3D annotations in the CAD model 102 to generate 2D annotations 122 that can be attached to the resulting synthetic camera images 114.

An example pseudo code describing an implementation of the above-described operations performed in the second step by the 3D image labeler 120 is provided below.

### Example: Matching Global 3D Bounding Boxes to Camera Position and FOV

```
# Load all the needed/available information
part_object = load_part(‘part1.step’) #
Load the cad model
cylind_faces = load_face(‘face.obj’) #
Load the cylindrical faces with
holes
3D_bbox_list = load_txt(‘bounding_box.txt’) #
Load the 3D bounding box info
for the holes
cam_positions = load_cameraProp(“camerainfo.txt”)
# Initialize the hole dictionary for keeping all relevant meta data
hole_dictionary = { }
# Generate and extend camera field of view
camera_fovs = extend_fov(cam_positions)
# Loop around each camera field of view
For each cam_fov in camera_fovs:
  # Loop around each cylindrical face that has a hole
  for each face_hole in cylind_faces:
    # Check whether the cylindrical face and camera FOV overlaps
    or not
    If face_hole inside of cam_fov:
      # Store the hole for the cam position
      hole_dictionary.ID = cam_positions.ID
      # Apply transformation matrix to convert the 3D bounding
      box into 2D bounding box using geometrical relationship
      between the camera (always rectangular)
      2d_bbox = convert_bbox(3D_bbox_list[i])
      # Store 2D bounding box inside the hole dictionary
      hole_dictionary.bbox = 2d_bbox
```

In some embodiments, especially for detecting logos, an image labeler may be configured by manually annotating some synthetic camera images 114 by localizing logos to train a machine learning model. Since logos usually appear in one place for each part, a small number (e.g., 100) of annotated images may suffice for training the model. The trained machine learning model may be used by the image labeler to generate annotations for additional images 114.

While the image renderer 104 may be capable of rendering high-quality photorealistic images, the present inventors recognize that a machine learning model trained using the rendered synthetic camera images 114 directly can lead to false positives in detecting nominal surface features such as holes in real images. To minimize false positives and generalize the model training to a range of real-world scenarios, an image blender 124 is included in the pipeline 100, as shown in FIG. 1. According to disclosed embodiments, the image blender 124 is configured to process the synthetic camera images 114, by randomly superimposing background textures and/or artifacts on a part surface, which are obtained from a set of real images, on the synthetic camera images 114.

For superimposing a real background on a synthetic camera image 114, the image blender 124 may perform the following operations. In a first step, background pixels in the image 114 may be determined. This operation may include segmentation of the image 114 utilizing a segmentation mask determined based on the background color extracted from the image meta data, as described above in the context of a 2D image labeler 116. To aid this operation, the image renderer 104 may be configured to apply a uniform background color (e.g., conveyor color) respectively to each synthetic camera image 114. In embodiments where a 2D image labeler 116 is employed, the background pixels may already be known via the 2D image labeler 116, and hence this operation need not be repeated.

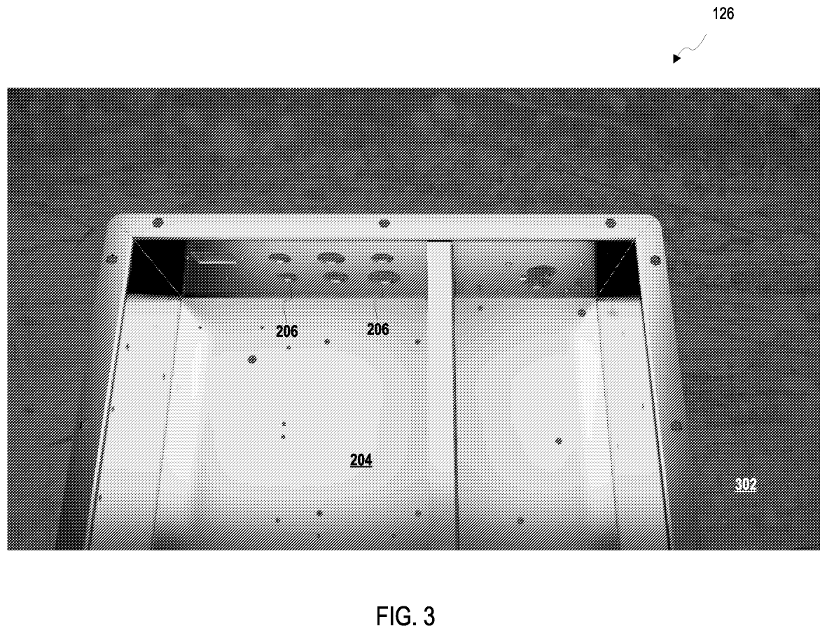

Having identified the background pixels, the image blender 124 may randomly select a background texture, from a set of real images of the inspection environment, and apply the selected background texture on the identified background pixels using a blending algorithm. An example of a blending algorithm suitable for the present application can involve a linear blending using addweighted( ) function in OpenCV, among many others. In some embodiments, the real images may pertain to multiple inspection environments (e.g., different conveyors) to achieve a high degree of model generalization. An example of a processed image 126 generated by the image blender 124 is shown in FIG. 3, wherein the image blender 124 has superimposed a real background texture 302. Note that since pixels within the holes 206 are also identified as background pixels using the segmentation mask, the applied background texture 302 also extends into the holes 206.

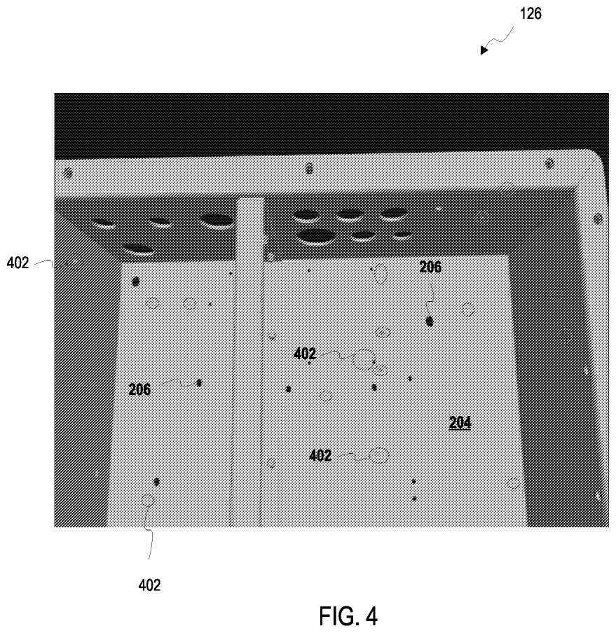

To further generalize the machine learning model to real-world conditions, the image blender 124 may process a rendered synthetic camera image 114 by superimposing artifacts on a part surface in the image 114. For example, the artifacts on the part surface may correspond to oil smudges, reflections and/or other real-world conditions. For this purpose, a library of such artifacts may be created and stored. These artifacts may be obtained from a set of real images of parts based on image segmentation. The set of real images may pertain to one or multiple inspection environments. The image blender 124 may randomly select an artifact from the library and position the selected artifact at a random location on a part surface in the image 114 using a suitable blending algorithm, such as described above. The pixels forming a part surface in the image 114 may be determined, for example, using the segmentation mask based on a uniform background color as described above. In particular, the image blender 124 may ensure that the randomly positioned artifacts do not overlap with annotated nominal surface features in the synthetic camera images 114. An example of a processed image 126 generated by the image blender 124 is shown in FIG. 4, wherein the image blender 124 has randomly superimposed a number of artifacts (identified via circles 402) on one or more surfaces of the part 204. Note that the superimposed artifacts 402 do not overlap with the holes 206.

Continuing with reference to FIG. 1, the processed synthetic camera images 126 generated by the image blender 124 and the annotations 118, 122 generated by the image labeler 116, 120 may be utilized by a model trainer 130 for training a machine learning model. In embodiments, the machine learning model may include a deep neural network (DNN), especially a deep convolutional network, among others. The model trainer 130 may be configured to train the machine learning model in a supervised learning process, by inputting the images 126 (which may define a DNN input layer) and comparing a predicted output of the model (which may define a DNN output layer) against the annotations 118, 122 as ground truth to compute a loss function. The learning process may comprise iteratively adjusting learnable model parameters (e.g., DNN weights and biases), for example, using a method of gradient descent, over a set of images 126, such that the loss function is minimized. The set of images 126 used for model training may pertain to different parts in multiple inspection environments. In some embodiments, the machine learning model may be pretrained on an available image database for object recognition, such as ImageNet, and fine-tuned to the specific industrial use-case using the model trainer 130. After training by the model trainer 130, the machine learning model may be validated using real images of parts on the production line.

Industrial cameras used for vision-based quality inspection usually have high resolutions, typically ranging from 16 megapixels to 24 megapixels, which can lead to a large amount of data. However, depending on their architecture, industrial deep learning models typically work on low or medium resolution images. For example, most existing deep learning models are capable of ingesting images with a size of 128×128 to 1024×1024 pixels. Resizing of a high-resolution image (e.g., 5000×3000 pixels) to a low-resolution image (e.g., 1024×1024 pixels) can lead to loss of critical information, since many of the nominal surface features are small (e.g., 1 mm or less). Moreover, there is high correlation between the model input size and its complexity. Considering that industrial inspection use-cases are required to achieve a low cycle time, it is desirable for the model to have low complexity.

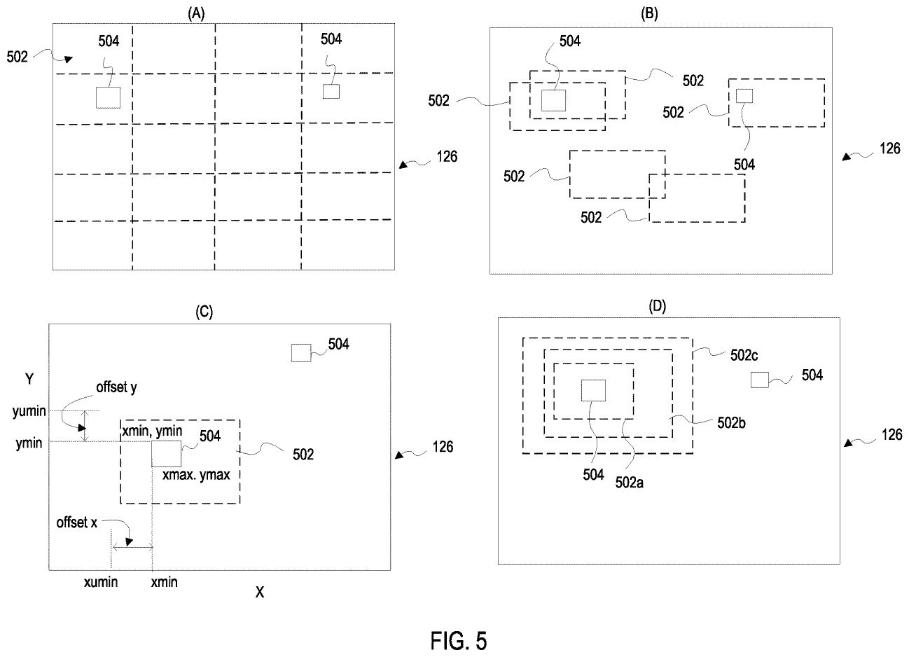

To address the above challenges, a data pre-processing step may be introduced to extract smaller patches (having reduced number of pixels) from high-resolution images, so that the extracted patches can be ingested and processed efficiently by the machine learning model. Consistent with a disclosed embodiment, the pipeline 100 may include a patch extractor 128 configured to extract a number of patches of a defined patch-size from each synthetic camera image 126 to be used for model training, for example, using one or more modalities of patch extraction as described in FIG. 5. The annotations 118, 122 generated by the image labeler 116, 120 may be adjusted and assigned to the respective patches in the images where they are located. The patches with the assigned annotations may now form the training dataset for the model trainer 130.

Referring to FIG. 5, according to a first modality of patch extraction (A), a set of ordered patches 502 may be extracted from a whole image 126. In the shown example, the patches 502 are non-overlapping, and may be extracted by dividing the image 126 based on a specified number of rows and columns based on the defined patch-size. In an alternate example (not shown), the ordered patches 502 may have an overlap, and may be extracted by defining a sliding window based on the defined patch size and an overlap degree (e.g., specified as a percentage or number of pixels). According to a disclosed embodiment, only those patches 502 that contain an annotation or bounding box 504 encapsulating a detected surface feature may be saved in the training dataset, and the remaining patches 502 discarded.

According to a second modality of patch extraction (B), a set of patches 502 may be extracted from a whole image 126 in a randomized manner based on a defined patch size for a specified number of trials. In each trial, the patch extractor 128 may extract a randomized patch 502 and check if an annotation or bounding box 504 encapsulating a detected surface feature is inside the randomized patch 502. If yes, the randomized patch 502 may be saved in the training dataset, and if not, the patch 502 may be discarded. As seen, in this modality, the same surface feature (bounding box 504) can be present in multiple randomized patches 502, but at different positions, thereby offering different perspectives. This can provide a large degree of variation in model training suitable for generalizing the model to different parts and inspection environments. In one embodiment, to minimize redundancy in the training dataset, the patch extractor 128 may apply a condition to discard extracted patches 502 which have more than a specified degree of overlap (e.g., >90% overlap) with a previously saved patch 502.

A third modality of patch extraction (C) may be based on extracting randomized patches 502 from a whole image 126 by offsetting the field of view of a detected surface feature, defined by a bounding box 504. In this modality, the patch extractor 128 may locate an annotation or bounding box 504 in the image 126 and define offsets from the edges of the bounding box 504 along X and Y axes of the image 126. The offsets are respectively designated in the drawing as offset x and offset y. The patch extractor 128 may select the offsets (offset x and offset y) randomly, such that each of these offsets is lower than the half the length of the bounding box 504 along the respective axis. Based on the defined offsets and the coordinates xmin, ymin of the bounding box 504, boundary positions xumin, yumin may be determined along the X and Y axes respectively. The patch extractor 128 may then extract randomized patches 502 around the bounding box 504 such that the edges of each randomized patch 502 lie within the defined offsets along the X and Y axes respectively, i.e., between xmin and xumin along the X axis and between ymin and yumin along the Y axis. The above operation may be repeated for multiple bounding boxes 504 in the image 126. Using this modality can enable different neighborhoods or neighboring pixels of each annotated surface feature (bounding box 504) to be taken into account for model training, making the model more robust and generalizable to different parts and inspection environments.

A fourth modality of patch extraction (D) may be based on extracting randomized patches by scaling the field of view of a detected surface feature (defined by a bounding box 504) in an image 126. In this modality, the patch extractor 128 may locate an annotation or bounding box 504 in the image 126 and extract a number of randomized patches 502a, 502b, 502c, . . . around the bounding box 504 with different scaling factors to capture different fields of view, maintaining a fixed aspect ratio. For example, the patch size of the extracted patches 502a, 502b, 502c, . . . may range anywhere from 512×512 pixels to 2048×2048 pixels. A higher patch size may capture a larger field of view around the bounding box 504, while a smaller patch size may capture a smaller field of view around the bounding box 504. While extracting the randomized patches 502a, 502b, 502c . . . , offsets of the patches with respect to the bounding box 504 may also be randomized, similar to the third modality (C). In a next step, the patch extractor 128 may re-size the extracted patches 502a, 502b, 502c, . . . , including the bounding box 504 contained therein, to conform with the defined patch size (e.g., 512×512 pixels). The above operation may be repeated for multiple bounding boxes 504 in the image 126. Using this modality can enable zoomed-in and zoomed-out views of each annotated surface feature (bounding box 504) to be taken into account for model training, making the model more robust and generalizable to different parts and inspection environments.

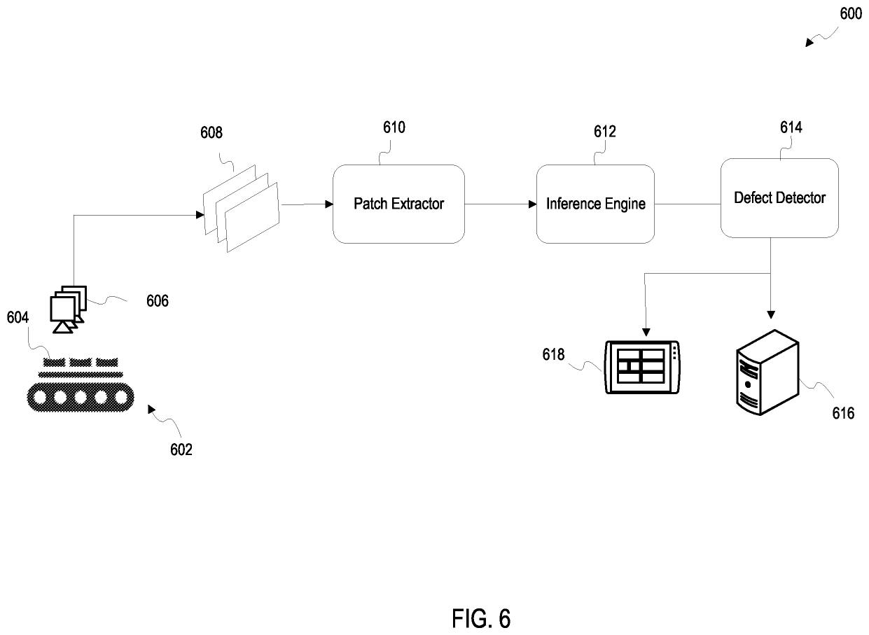

FIG. 6 shows an example of a vision-based inspection system 600 for a production line. The various modules, such as the patch extractor 610, the inference engine 612 and the defect detector 614, described herein, including components thereof, may be implemented by a computing system in various ways, for example, as hardware and programming. The programming for the modules 610, 612, 614 may take the form of processor-executable instructions stored on non-transitory machine-readable storage mediums and the hardware for the engines may include processors to execute those instructions. In a non-limiting example implementation, the computing system may comprise an edge computing device, such as an industrial PC, wherein the modules 610, 612, 614 may be deployed as one or more apps. The computing system may be provided with one or more processors such as GPUs or deep learning processors such as neural processing units (NPU) to run the deployed app(s) in a computationally efficient fashion.

Referring to FIG. 6, the system 600 may comprise one or more cameras 606 arranged in an inspection environment 602 of a production line. The production line may comprise a queue of manufactured parts 604 that may be transported to the inspection environment 602 by a conveyor. In examples, the manufactured parts 604 may comprise die-cast parts, stamped metal parts, injection molded plastic parts, among others. During operation, each of the one or more cameras 606 may be triggered to capture one or more real images 608 of each manufactured part 604. The inference engine 612 may be configured to process an input based on the real images 608 to detect nominal surface features using the above-described trained machine learning model.

Consistent with disclosed embodiments, the system 600 may include a patch extractor 610 configured to extract patches from each captured real image 608. The extracted patches for each image 608 may comprise, in this case, ordered patches with a defined patch size as described in the first modality (A) in FIG. 5. The extracted patches may be provided to the inference engine 612, which may use the machine learning model to detect and localize nominal surface features on the patches. Ordered patches of an image may then be stitched together to recreate the whole image with annotations or bounding boxes around the detected nominal surface features. In certain embodiments, depending on the resolution of the images 608 and/or the architecture of the machine learning model, the input to the inference engine 612 may comprise whole images 608. The patch extractor 610 may be obviated in this case.

The results of the inference engine 612 may be provided to a defect detector 614. The defect detector 614 may be configured to determine a defect in the manufactured part 604 by comparing a count of the nominal surface features (e.g., holes) detected by the inference engine 612 to an expected count of nominal surface features obtained from a reference image of the same part. The reference image may comprise for example, a synthetic camera image generated by camera simulation with the same field of view as the real image 608.

In some embodiments, especially for very large parts, multiple images with different fields of views may be necessary to achieve coverage for the whole part. The multiple fields of views may be captured by using multiple cameras at different positions and/or by triggering a camera at a given position at multiple instances as the part is moved (e.g., by a conveyor). In such a scenario, the defect detector 614 may be configured to detect a defect by performing a fusion of the results provided by the inference engine 612 for multiple real images 608 of the same part 604 with different fields of views.

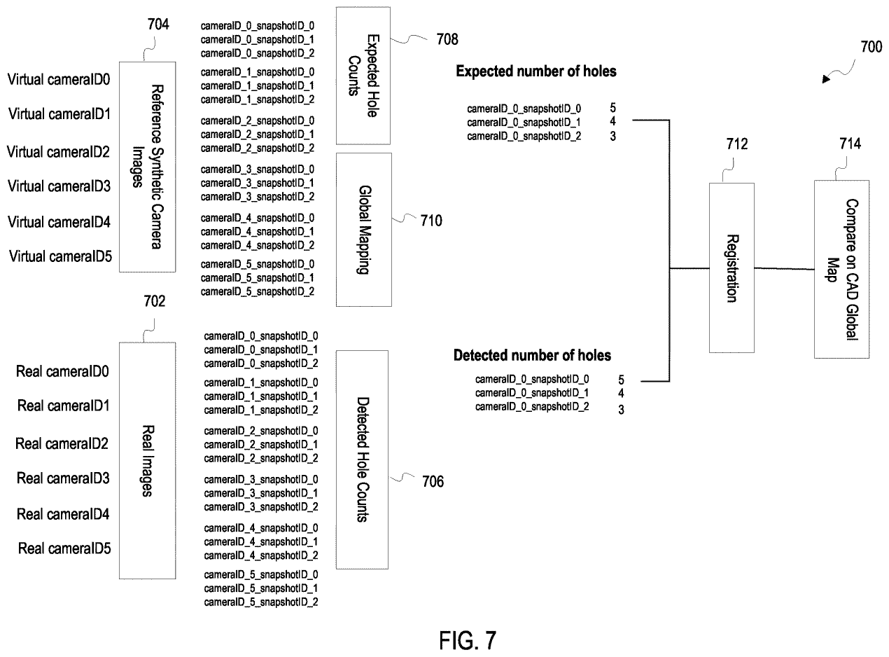

FIG. 7 illustrates an example workflow 700 for fusion of inference results for defect detection according to an embodiment. In the illustrated example, a set of real images 702 including different fields of views of a part may be acquired by way of 5 cameras, each of which may be triggered at 3 instances to capture 3 different snapshots of the part. A set of synthetic camera images 704 may be generated by camera simulation based on the positions and trigger instances of 5 virtual cameras that correspond to the real cameras. Each synthetic camera image 704 may thus form a reference image for a real image 702 with a corresponding field of view. In this example, and without loss of generality, the nominal surface features being detected include holes. A count of detected holes for each field of view may be obtained from the inference engine 612 (operational block 706). The defector detector 614 may determine the expected count of holes by identifying holes in the corresponding reference images 704 (operational block 708). The defect detector 614 may then globally map the holes identified in the reference images 704 on to the CAD model 102 of the part (operational block 710). Next, the defect detector 614 may register each of the real images 702 with its corresponding reference image 704 (operational block 712). After registration, the defect detector 614 may compare a global mapping of the holes detected in the real images 702 to the global mapping of the holes identified in the reference images 704 on the CAD model 102 (operational block 714), to determine if the expected count of nominal surface features is met.

Referring back to FIG. 6, based on the output of the defect detector 614, appropriate control action may be executed. Examples of control action may include, for example, isolating a defective part from production, shutting down production, and so on. The control action may be executed automatically, semi-automatically, or manually, responsive to the output of the defect detector 614, specifically, a positive defect detection in one or more manufactured parts 604 in the production line. For example, in one embodiment, as shown in FIG. 6, the system 600 may include a field controller 616 for automatically executing a control action to control the production line based on the output of the defect detector 614. In embodiments, the field controller 616 may comprise or be integrated with automation system equipment such as PLCs (Programmable Logic Controllers), drives, etc. for executing the control action. Additionally, or alternately, the output of the defect detector 614 (e.g., presence and location of identified defects) may be visualized and displayed to an operator via an HMI device 618, to enable an operator to initiate a control action.

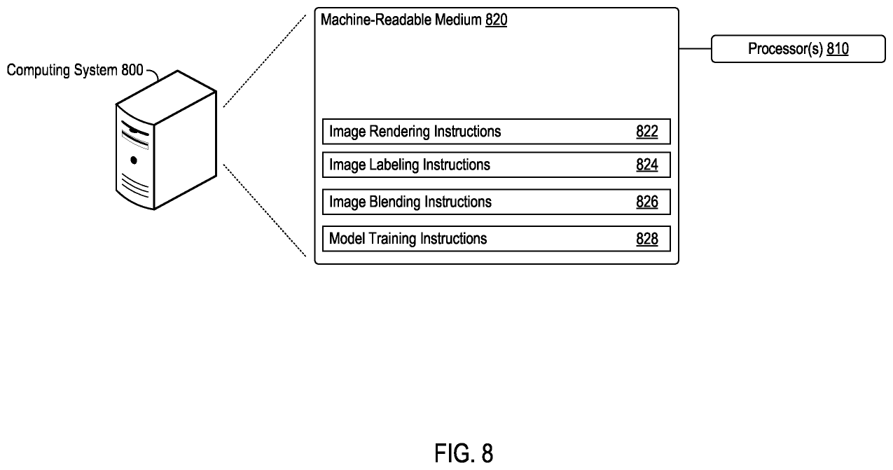

FIG. 8 shows an example of a computing system 800 that can support vision-based inspection of parts on a production line according to disclosed embodiments. In examples, the computing system 800 may be configured as a powerful multi-GPU workstation, among other types of computing devices. The computing system 800 includes at least one processor 810, which may take the form of a single or multiple processors. The processor(s) 810 may include a one or more CPUs, GPUs, microprocessors, or any hardware devices suitable for executing instructions stored on a memory comprising a machine-readable medium. The computing system 800 further includes a machine-readable medium 820. The machine-readable medium 820 may take the form of one or more media including any non-transitory electronic, magnetic, optical, or other physical storage device that stores executable instructions, such as image rendering instructions 822, image labeling instructions 824, image blending instructions 826 and model training instructions 828, as shown in FIG. 8. As such, the machine-readable medium 820 may be, for example, Random Access Memory (RAM) such as a dynamic RAM (DRAM), flash memory, spin-transfer torque memory, an Electrically-Erasable Programmable Read-Only Memory (EEPROM), a storage drive, an optical disk, and the like.

The computing system 800 may execute instructions stored on the machine-readable medium 820 through the processor(s) 810. Executing the instructions (e.g., the image rendering instructions 822, the image labeling instructions 824, the image blending instructions 826 and the model training instructions 828) may cause the computing system 800 to perform any of the technical features described herein, including according to any of the features of the image renderer 104, the image labeler 116 and/or 120, the image blender 124 and the model trainer 130 described above.

The systems, methods, devices, and logic described above, including the image renderer 104, the image labeler(s) 116, 120, the image blender 124 and the model trainer 130, may be implemented in many different ways in many different combinations of hardware, logic, circuitry, and executable instructions stored on a machine-readable medium. For example, these engines may include circuitry in a controller, a microprocessor, or an application specific integrated circuit (ASIC), or may be implemented with discrete logic or components, or a combination of other types of analog or digital circuitry, combined on a single integrated circuit or distributed among multiple integrated circuits. A product, such as a computer program product, may include a storage medium and machine-readable instructions stored on the medium, which when executed in an endpoint, computer system, or other device, cause the device to perform operations according to any of the description above, including according to any features of the image renderer 104, the image labeler(s) 116, 120, the image blender 124 and the model trainer 130. Computer readable program instructions described herein can be downloaded to respective computing/processing devices from a computer readable storage medium or to an external computer or external storage device via a network, for example, the Internet, a local area network, a wide area network and/or a wireless network.

The processing capability of the systems, devices, and engines described herein, including the image renderer 104, the image labeler(s) 116, 120, the image blender 124 and the model trainer 130 may be distributed among multiple system components, such as among multiple processors and memories, optionally including multiple distributed processing systems or cloud/network elements. Parameters, databases, and other data structures may be separately stored and managed, may be incorporated into a single memory or database, may be logically and physically organized in many different ways, and may be implemented in many ways, including data structures such as linked lists, hash tables, or implicit storage mechanisms. Programs may be parts (e.g., subroutines) of a single program, separate programs, distributed across several memories and processors, or implemented in many different ways, such as in a library (e.g., a shared library).

Although this disclosure has been described with reference to particular embodiments, it is to be understood that the embodiments and variations shown and described herein are for illustration purposes only. Modifications to the current design may be implemented by those skilled in the art, without departing from the scope of the patent claims.

1. A system for vision-based inspection of manufactured parts on a production line using one or more cameras in an inspection environment, the system comprising:
one or more processors, and
a non-transitory memory storing algorithmic modules executable by the one or more processors, the algorithmic modules comprising:
an image renderer configured to generate multiple synthetic camera images of a part utilizing a CAD model of the part by simulating the inspection environment and the one or more cameras based on randomization of a number of operational and environmental parameters,
an image labeler configured to generate annotations in the synthetic camera images by automatically detecting nominal surface features on the part in the synthetic camera images,
an image blender configured to process the synthetic camera images by randomly superimposing background textures and/or artifacts on a part surface, which are obtained from a set of real images, on the synthetic camera images, and
a model trainer configured to utilize the processed synthetic camera images and the generated annotations to train a machine learning model to detect the nominal surface features on real images of manufactured parts on the production line captured by the one or more cameras in the inspection environment.

2. The system according to claim 1, wherein the randomized environmental and operational parameters are selected from the group consisting of: part orientation, part translation, conveyor speed, vibration in camera position, cycle time, conveyor dimensions, background color and texture, part color and texture, and ambient lighting

3. The system according to claim 1, wherein the nominal surface features include holes.

4. The system according to claim 3,
wherein the image renderer is configured to apply a uniform background color to the synthetic camera images in a randomized manner such that the background color is distinct from a part color, and
wherein the image labeler is configured to detect holes on each synthetic camera image utilizing a segmentation mask determined based on the background color.

5. The system according to claim 4, wherein the image labeler is configured to perform, for each synthetic camera image:
segment the synthetic camera image utilizing the segmentation mask,
determine contours in the segmented image bounding regions having the background color,
identify regions bounded by contours whose area falls within a defined range, and
generate annotations in the synthetic camera image based on a position of each identified region.

6. The system according to claim 1, wherein the image labeler is configured to:
detect nominal surface features in the CAD model of the part based on a geometrical property of the nominal surface features,
generate 3D annotations in the CAD model by extracting positions of the detected nominal surface features, and
transform the 3D annotations in the CAD model, which overlap with a simulated camera field of view, from a 3D CAD space to a 2D camera space, to generate annotations in the synthetic camera images.

7. The system according to claim 1, wherein the image labeler is configured to generate the annotations by drawing bounding boxes around the detected nominal surface features.

8. The system according to claim 1, wherein the image blender is configured to process the synthetic camera images by randomly positioning artifacts on a part surface, selected from a library of artifacts segmented from the set of real images, such that the randomly positioned artifacts do not overlap with annotated nominal surface features in the synthetic camera images.

9. The system according to claim 1, wherein the algorithmic modules further comprise a patch extractor configured to extract a number of patches of a defined patch-size from each synthetic camera image, and assign the annotations generated by the image labeler to the respective patches,
wherein the patches with the assigned annotations are utilized by the model trainer for training the machine learning model.

10. The system according to claim 9, wherein the patch extractor is configured to perform, for each synthetic camera image:
for a specified number of trials,
extract a randomized patch, and
if an annotated nominal surface feature is inside the randomized patch, then save the randomized patch, else discard the randomized patch.

11. The system according to claim 9, wherein the patch extractor is configured to perform, for each synthetic camera image:
locate an annotated nominal surface feature defined by a bounding box,
define offsets from the edges of the bounding box along X and Y axes of the synthetic camera image, and
extract randomized patches around the bounding box such that the edges of each randomized patch lie within the defined offsets along the X and Y axes respectively.

12. The system according to claim 9, wherein the patch extractor is configured to perform, for each synthetic camera image:
locate an annotated nominal surface feature defined by a bounding box, and
extract randomized patches around the bounding box with different scaling factors to capture different fields of view, maintaining a fixed aspect ratio, and
re-size the extracted patches including the bounding box contained therein to conform with the defined patch size.

13. The system according to claim 1, wherein the algorithmic modules further comprise:
an inference engine configured to process an input based on at least one real image of a manufactured part on the production line using the trained machine learning model to detect nominal surface features, and
a defect detector configured to compare a count of the nominal surface features detected by the inference engine to an expected count of nominal surface features obtained from a reference image of the part, to determine a defect in the manufactured part.

14. The system according to claim 13,
wherein the input to the inference engine is based on a plurality of real images of the manufactured part with different fields of views,
wherein the reference image comprises a plurality of reference synthetic camera images having corresponding fields of views with respect to the plurality of real images, and
wherein the defect detector is configured to:
determine the expected count of nominal surface features by identifying nominal surface features in the reference synthetic camera images,
globally map the nominal surface features identified in the reference synthetic camera images on to the CAD model of the part,
register each of the real images with one of the reference synthetic camera images with a corresponding field of view, and
compare a global mapping of the nominal surface features detected in the real images to the global mapping of the nominal surface features identified in the reference synthetic camera images on the CAD model, to determine if the expected count of nominal surface features is met.

15. A computer-implemented method for vision-based inspection of manufactured parts on a production line using one or more cameras in an inspection environment, the method comprising:
generating multiple synthetic camera images of a part utilizing a CAD model of the part by simulating the inspection environment and the one or more cameras based on randomization of a number of operational and environmental parameters,
generating annotations in the synthetic camera images by automatically detecting nominal surface features on the part in the synthetic camera images,
processing the synthetic camera images by randomly superimposing background textures and/or artifacts on a part surface, which are obtained from a set of real images, on the synthetic camera images, and
utilizing the processed synthetic camera images and the generated annotations to train a machine learning model to detect the nominal surface features on real images of manufactured parts on the production line captured by the one or more cameras in the inspection environment.

16. A non-transitory computer-readable storage medium encoded with instructions that, when processed by a computing system, configure the computing system to perform the method according to claim 15.
